(19) United States
(12) Patent Application Publication
(10) Pub. No.: US 2005/0030711 A1
(43) Pub. Date: Feb. 10, 2005

(54) Heat dissipating device of power supply

(76) Inventor: Tsung-Yen Tsai, Taipei Hsien (TW)

Correspondence Address: Tsung-Yen Tsai, 235 Chung - Ho, Box 8-24, Taipei, TW

(21) Appl. No.: 10/634,674

(22) Filed: Aug. 6, 2003

(51) Int. Cl. H05K 5/00; H05K 7/20

(52) U.S. Cl. 361/687

(57) ABSTRACT

A heat dissipating device of a power supply is disclosed. The power supply is installed at a rear side of a computer. The power supply comprises a base and a cover. Power is conducted into a receptacle. A voltage of the power is reduced by an electric element and then is supplied to the computer. An upper end of the cover is formed with a through hole the size of which is expanded as large as possible in the upper end of the cover. A fan is installed in an interior of the through hole. A mask covers upon the through hole. The fan senses the temperature of the power supply and the rotation speed of the fan is adjustable. The fan sucks outer cool air to blow the interior electronic element. The air is vented out from a plurality of ventilating holes at the backside of the base.

### FIELD OF THE INVENTION

The present invention relates to heat dissipating devices, and particularly to a heat dissipating device of a power supply, wherein a fan is installed at an upper side of a power supply. The fan sucks outer cool air to blow the interior electronic element; and the air is vented out from a plurality of ventilating holes at the backside of the base.

### BACKGROUND OF THE INVENTION

Currently, since more and more peripherals are equipped to a computer, and thus the power supply of the computer must supply much power to the computer. As a result, the power supply dissipates more heat and thus heat to be dissipated is increased. To effective dissipate power of the power supply of a computer is an important problem in the prior art.

In the prior art, a fan is installed at a backside of the power supply for sucking hot air within the power supply and then blowing the air out of the power supply. However, backside of the power is smaller so that the size of the fan is confined (in general, it has a size of approximate 6 centimeters). Therefore, heat dissipated is limited.

To improve the defect in the prior art, a further fan is installed at a front side of the power supply so as to increase the air suction ability of the power supply. The fan at the front side sucks air to blow the electric elements within the power supply and then the air is vented out by the fan at the rear side of the power supply, as shown in FIG. 1. The defect of this prior art is that the size of the fan at the front side must be confined by the fan at the rear side for retaining the equilibrium of the airflow in the power supply and reducing the lower frequency noises. Moreover, two fans are used and thus the cost is high and installation process is complicated. Moreover, the two fans have small sizes and thus they are rotated in a higher speed for satisfying the requirement in heat dissipation. As a result, the bearing and rollers are worn rapidly so that vibrations of the fans are large. This will make one feel uneasy.

### SUMMARY OF THE INVENTION

Accordingly, the primary object of the present invention is to provide a heat dissipating device of a power supply; a fan is installed in an interior of the through hole; the fan sucks outer cool air to blow the interior electronic element; the air is vented out from a plurality of ventilating holes at the backside of the base.

Another object of the present invention is to provide a heat dissipating device of a power supply wherein the power supply being installed at a rear side of a computer. The power supply comprises a base and a cover. Power is conducted into a receptacle at a back end of the base. A voltage of the power is reduced by an electric element and then is supplied to the computer. An upper end of the cover is formed with a through hole the size of which is expanded as large as possible in the upper end of the cover;

A further object of the present invention is to provide a heat dissipating device of a power supply, wherein the fan senses the temperature of the power supply and the rotation speed of the fan is adjustable. Thereby, the oscillation and noise can be reduced greatly.

The various objects and advantages of the present invention will be more readily understood from the following detailed description when read in conjunction with the appended drawing.

### BRIEF DESCRIPTION OF THE DRAWINGS

FIG. 1 is a schematic view showing the structure of the prior art heat dissipating structure of a power supply.

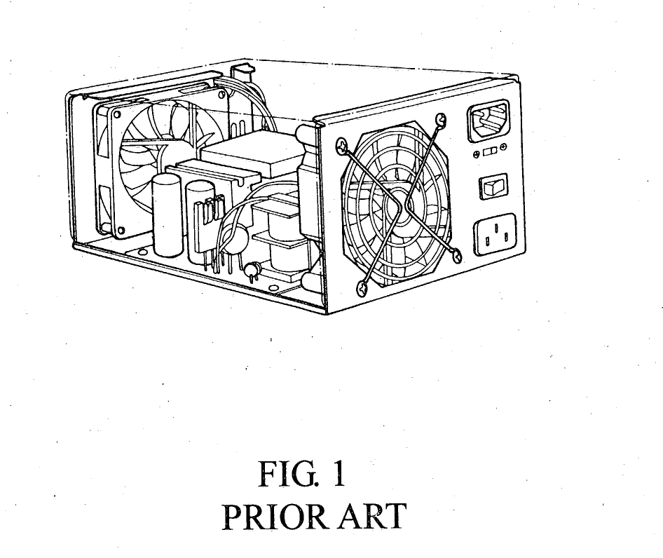

FIG. 2 is an exploded perspective view of the present invention.

FIG. 3 shows the perspective view of the present invention.

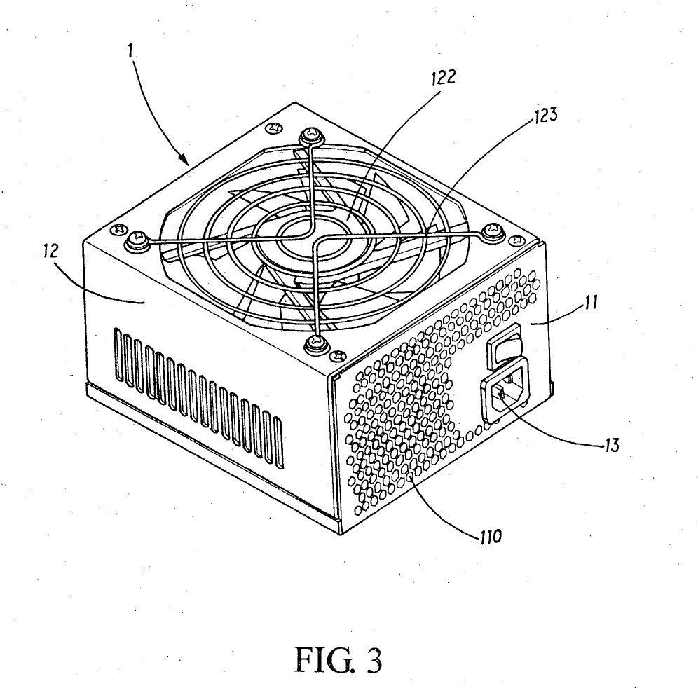

FIG. 4 is a schematic view showing the airflow of the present invention.

### DETAILED DESCRIPTION OF THE INVENTION

In order that those skilled in the art can further understand the present invention, a description will be described in the following in details. However, these descriptions and the appended drawings are only used to cause those skilled in the art to understand the objects, features, and characteristics of the present invention, but not to be used to confine the scope and spirit of the present invention defined in the appended claims.

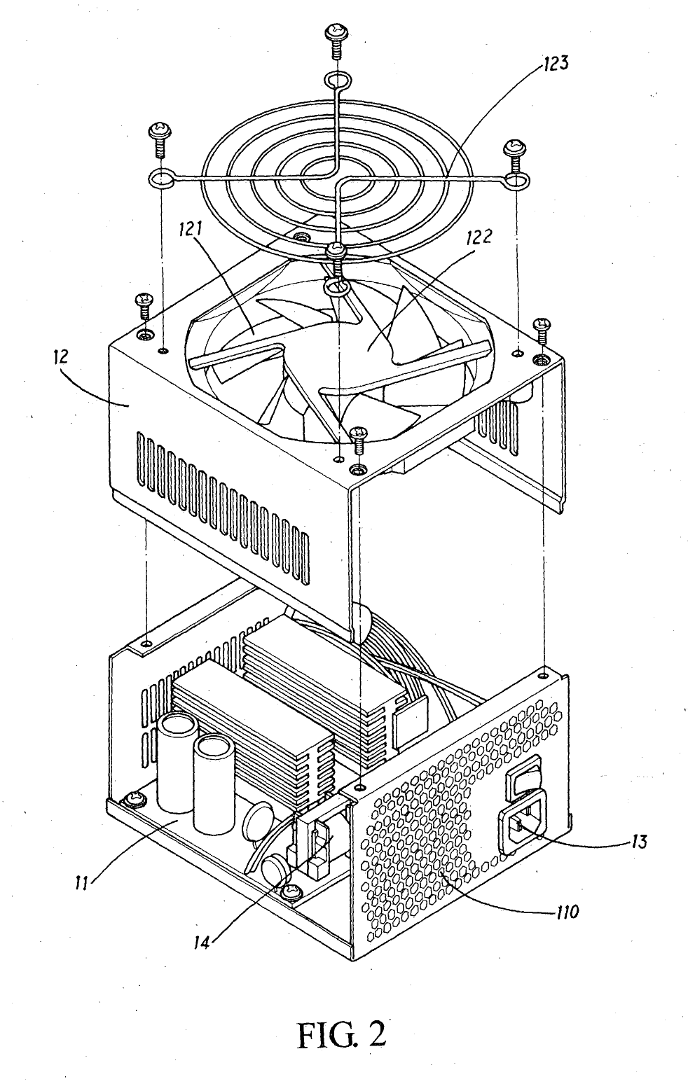

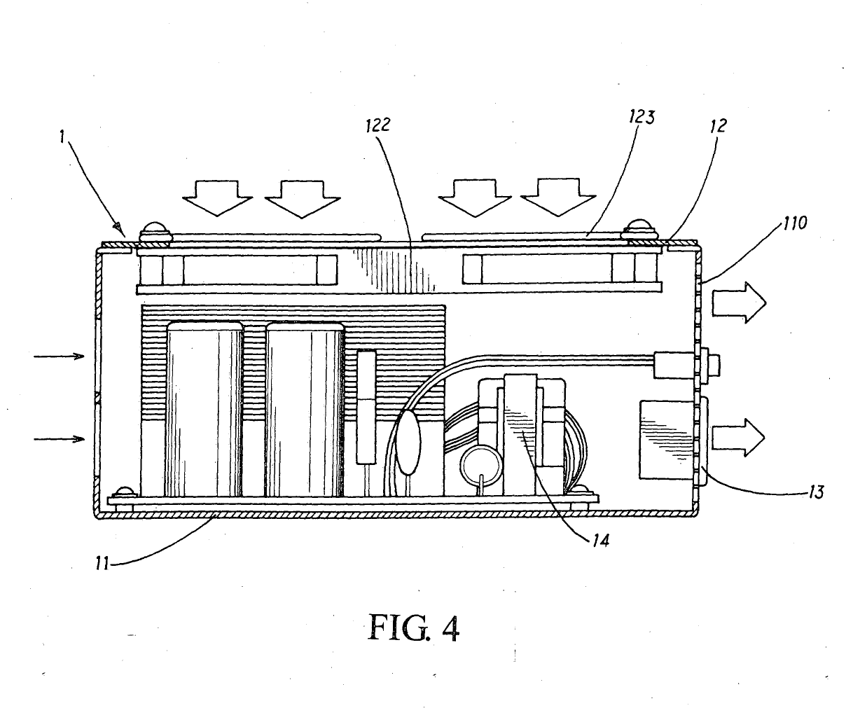

With reference to FIGS. 2 and 4, the heat dissipating device of a power supply of the present invention is illustrated. The power supply 1 is installed at a rear side of a computer. The power supply 1 includes a base 11, and a cover 12. Power is conducted into a receptacle 13 at a back side of the base 11. The voltage of the power is reduced by an electric element 14 and then is supplied to the computer. The feature of the present invention is that an upper end of the cover 12 is formed with a through hole 121 the size of which is expanded as large as possible in the upper end of the cover 12. A fan 122 is installed in an interior of the through hole 121. A mask 123 covers upon the through hole 121 for avoiding undesired object to enter into the through hole 121. The fan 122 can sense the temperature of the power supply 1 and the rotation speed of the fan 122 is adjustable for sucking outer cool air (referring to FIG. 4) to blow the interior electronic element 14. The air is vented out from the plurality of ventilating holes 110 at the back side of the base 11.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

1. A heat dissipating device of a power supply; the power supply being installed at a rear side of a computer; the power supply comprising a base and a cover; wherein power is conducted into a receptacle at a back side of the base; a voltage of the power is reduced by an electric element and then is supplied to the computer; an upper end of the cover is formed with a through hole the size of which is expanded as large as possible in the upper end of the cover; a fan is installed in an interior of the through hole; the fan sucks outer cool air to blow the interior electronic element; the air is vented out from a plurality of ventilating holes at the backside of the base.

2. The heat dissipating device of a power supply as claimed in claim 1, wherein a mask covers upon the through hole.

3. The heat dissipating device of a power supply as claimed in claim 1, wherein the fan senses the temperature of the power supply and the rotation speed of the fan is adjustable.
